(19) United States
(12) Patent Application Publication
(10) Pub. No.: US 2026/0155161 A1
(43) Pub. Date: Jun. 4, 2026

(54) CONTROL APPARATUS BASED ON VOLTAGE DROP AND METHOD THEREOF

(71) Applicants: Hyundai Motor Company, Seoul (KR); Kia Corporation, Seoul (KR)

(72) Inventors: Seul Gi Kim, Hwaseong-Si (KR); Hae Yoon Jung, Hwaseong-Si (KR); Kyeong Chan Lee, Hwaseong-Si (KR); Eon Ryeol Jeon, Hwaseong-Si (KR); Sang Sub Um, Hwaseong-Si (KR); Jae Dong Shin, Hwaseong-Si (KR)

(21) Appl. No.: 19/251,214

(22) Filed: Jun. 26, 2025

(30) Foreign Application Priority Data
Dec. 3, 2024 (KR) 10-2024-0177779

(51) Int. Cl. G11C 5/14; G06F 1/30

(52) U.S. Cl. CPC G11C 5/147; G06F 1/305

(57) ABSTRACT

A control apparatus based on a voltage drop and a method thereof are provided. The control apparatus includes a communication device that communicates with a host and a memory device, a processor that, if a voltage applied to the memory device drops, determines a state of power supply and controls operations of the memory device and the host based on the determined state of the power supply, and storage storing at least one instruction for execution by the processor.

### CROSS-REFERENCE TO RELATED APPLICATION

This application claims the benefit of priority to Korean Patent Application No. 10-2024-0177779, filed in the Korean Intellectual Property Office on Dec. 3, 2024, the entire contents of which are incorporated herein by reference.

### TECHNICAL FIELD

The present disclosure relates to a control apparatus for performing control based on a voltage drop and a method thereof, and more particularly, to a control apparatus for preventing loss of data stored in a memory and stabilizing an operation of a system.

### BACKGROUND

A storage device is a device for storing data. The storage device may be under control of and/or part of a host device, such as a computer, a smartphone, or an electronic control unit (ECU). The storage device may include a memory device (e.g., a memory) for storing data and a memory controller (e.g., control device, control circuit, etc.) for controlling the memory device. The memory device may be divided into a volatile memory device (e.g., a volatile memory) and a non-volatile memory device (e.g., a non-volatile memory).

The volatile memory device may be/comprise a memory device that stores data only if power is supplied and loses the stored data if power supply is blocked/stopped. The volatile memory device may be a static random access memory (SRAM), a dynamic random access memory (DRAM), or the like.

The non-volatile memory device may be a memory device that maintains data even without being supplied data (e.g., does not lose data although power is blocked. The non-volatile memory device may be a read only memory (ROM), a programmable ROM (PROM), an electrically programmable ROM (EPROM), an electrically erasable and programmable ROM (EEPROM), a flash memory, or the like.

The above-mentioned memory device may receive a power voltage and may perform a storage operation. However, there may occur a fault in which data (e.g., a program instruction or the like) stored in the memory device is damaged and/or lost, at least in part, if the supplied voltage is suddenly blocked or drops below a certain level. For example, a memory device of a vehicle may store data associated with a vehicle moving system including electronically controlled features of a vehicle, such as a sunroof, a power tailgate, a power door, and the like. If a fault occurs in the memory device, there may occur a problem in which the vehicle moving system does not operate, operates incorrectly, and/or is stopped. There is a need for a control apparatus for addressing these and related problems.

The above information disclosed in this Background section is only for enhancement of understanding of the background of the disclosure, and therefore it may contain information that does not form the prior art that is already known in this country to a person of ordinary skill in the art.

### SUMMARY

The following summary presents a simplified summary of certain features. The summary is not an extensive overview and is not intended to identify key or critical elements.

Systems, apparatuses, and methods are described for control based on power supply to a memory device. A control apparatus may comprise: a communication interface configured to communicate with a host device and a memory device associated with the host device; a processor; and a storage storing instructions that, when executed, configure the processor to: receive, from a voltage sensor, an indication of a drop in a voltage being supplied to the memory device; determine, based on the indication of the drop in the voltage, a state of a power supply supplying the voltage to the memory device; and control, based on the determined state of the power supply, one or more operations of the memory device and the host device.

A control method performed by an apparatus may comprise: receiving, by a processor of the apparatus from a voltage sensor, an indication of a drop in voltage being supplied to a memory device associated with a host device; determining, by the processor and based on the indication of the drop in voltage, a state of a power supply supplying the voltage to the memory device; and controlling, by the processor and based on the determined state of the power supply, one or more operations of the memory device and the host device.

These and other features and advantages are described in greater detail below.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating a configuration of a vehicle system including a control apparatus based on a voltage drop according to an example of the present disclosure;

FIG. 2 is a block diagram of a control apparatus based on a voltage drop according to an example of the disclosure;

FIGS. 3A, 3B, and 3C are an example of describing an operation of a processor according to an example of the present disclosure;

FIG. 4 is a flowchart for describing a control method based on a voltage drop according to example of the present disclosure;

FIG. 5 is a flowchart for describing in detail a control method based on a voltage drop according to example of the present disclosure;

FIG. 6 is a flowchart for describing in detail a control method based on a voltage drop according to example of the present disclosure;

FIG. 7 is a flowchart for describing in detail a control method based on a voltage drop according to example of the present disclosure; and

FIG. 8 is a block diagram illustrating a computing system for a control apparatus based on a voltage drop according to an example of the present disclosure.

### DETAILED DESCRIPTION

Hereinafter, some examples of the present disclosure will be described in detail with reference to the exemplary drawings. In adding the reference numerals to the components of each drawing, it should be noted that the identical component is designated by the identical numerals even when they are displayed on other drawings. Further, in describing the example of the present disclosure, a detailed description of well-known features or functions will be ruled out in order not to unnecessarily obscure the gist of the present disclosure.

In describing the components of the example of the present disclosure, terms such as first, second, “A”, “B”, (a), (b), and the like may be used. These terms are only used to distinguish one component from another component, but do not limit the corresponding components irrespective of the order or priority of the corresponding components. Furthermore, unless otherwise defined, all terms including technical and scientific terms used herein have the same meaning as being generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B. “One or more of” is synonymous with “at least one of” herein.

Throughout the present disclosure, references to components, units, devices or modules generally refer to items that logically can be grouped together to perform a function or group of related functions. Like reference numerals are generally intended to refer to the same or similar components. Components, units, devices and modules may be implemented in software, hardware or a combination of software and hardware. The components, units, modules, devices and/or functions described above may be implemented and/or performed by one or more processors. For examples, the components, units, devices and/or modules may include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The components, units, devices and/or modules may also include software control module(s) implemented with a processor or logic circuitry for example. The components, units, devices and/or modules may include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware. One or more storage type media may include any or all of the tangible memory of computers, processors, or the like, or associated modules thereof, such as various semiconductor memories, tape drives, disk drives and the like, which may provide non-transitory storage at any time for software programming.

The expressions such as “comprise”, “may comprise”, “include”, “may include”, “have”, “may have”, etc. as used herein are intended to mean the presence of a characteristic (e.g., function, operation, component, etc.) and do not exclude the presence of other additional characteristics. That is, these expressions should be understood as open-ended terms that encompass the possibility that other examples are included.

A singular expression used herein may include the meaning of the plural unless otherwise stated in the context, which also applies to the singular expression described in the claims.

The expression “based on” as used herein is intended to describe one or more factors that influence an act or operation of determining or deciding described in a phrase or sentence including that expression, and this expression does not exclude any additional factors that influence the act or operation of determining or deciding.

If it is described that a component (e.g., a first component) is “connected” or “coupled” to another component (e.g., a second component) as used herein, it may mean that the component is not only directly connected or coupled to another component, but also connected or coupled through yet another component (e.g., a third component).

Depending on the context, the expression “configured to” as used herein may have meanings such as “set to”, “with the ability to”, “modified to”, “made to”, “to be able to”, etc. This expression is not limited to the meaning of “specially designed in hardware to”. For example, a processor configured to perform a specific operation may refer to a generic purpose processor capable of performing the specific operation by executing software, or to a special purpose computer structured through programming to perform the specific operation.

A controller (e.g., control device, controller device, control circuit, etc.) may include a communication device communicating with other controllers or a sensor to control one or more functions and/or operations in charge, a memory storing an operation system, a logic command, and input/output information, and/or one or more processors performing determination, calculation, and decision necessary for controlling the function in charge. A controller may include, for example, a processor, a central processing unit (CPU), a microchip, a logic, an application-specific integrated circuit (ASIC), memory, etc. A controller may manipulate and/or control other components in the system (e.g., vehicle).

A user interface may be a device through which a human user can interact with a device. The user interface may include an input interface that can receive an input from the human user and/or an output interface through which data or information can be output to the human user. An input interface may include, for example, a button, a knob, a toggle, a switch, a dial, a slider, a keyboard, a touchscreen, a microphone, a camera, a wheel, a pedal, a lever, etc. An output interface may include, for example, alight, a lamp, an indicator, a screen, a display, a console, a meter, a gauge, a speaker, etc.

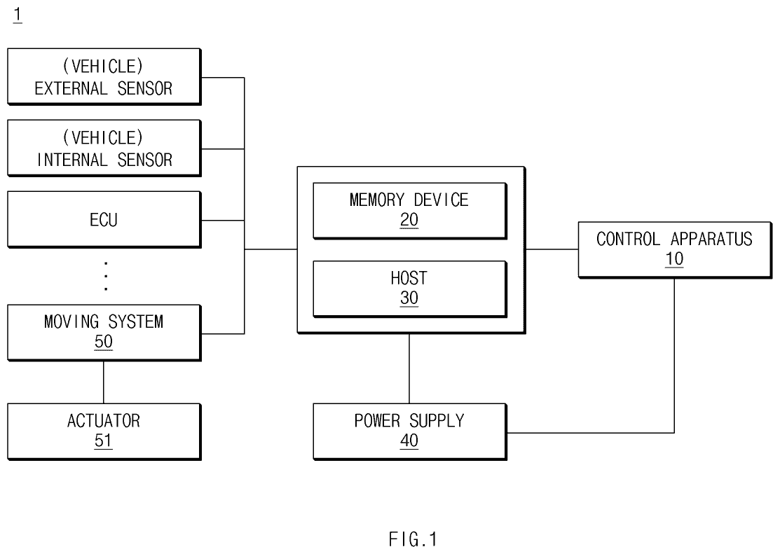

Hereinafter, examples of the present disclosure will be described in detail with reference to FIGS. 1 to 8.

FIG. 1 is a block diagram illustrating a configuration of a vehicle system 1 including a control apparatus 10 based on a voltage drop according to an example of the present disclosure.

A description will be given of an example of the control apparatus 10 included in the vehicle system 1 for convenience in FIG. 1, but the present disclosure is not limited to a control device for a vehicle system. The control apparatus 10 according to the present disclosure is applicable to other electronic devices, as well as the vehicle system 1.

Referring to FIG. 1, the vehicle system 1 may include the control apparatus 10, a memory device 20, a host 30, a power supply 40, a moving system 50, an actuator 51, one or more vehicle internal and/or external sensors (e.g., camera, LIDAR, RADAR, blind spot monitoring sensor, line departure warning sensor, parking sensor, light sensor, rain sensor, traction control sensor, anti-lock braking system sensor, tire pressure monitoring sensor, seatbelt sensor, airbag sensor, fuel sensor, emission sensor, throttle position sensor, etc.), an ECU, and the like.

The power supply 40 may supply a power voltage to the vehicle system 1 and/or the memory device 20. The power voltage supplied to the memory device 20 may be instantaneously overshot or undershot, according to a power supply condition of the power supply 40 (e.g., an power and/or voltage output by the power supply and measured by a power and/or voltage sensor) and/or power consumption of the memory device 20 (e.g., measured by a sensor associated with and/or of the memory device 20, and reported by the sensor and/or memory device 20). For example, the power supplied may be determined to overshoot or under shoot based on the measured power and/or voltage being above or below a set value and/or consumption value based on a measured power consumption. For example, the power supplied may be determined to overshoot if the power/voltage supplied is at least a first threshold value above the set value or consumption value. The power supplied may be determined to undershoot if the power/voltage supplied is at least a second threshold value below the set value or consumption value. If an undershot or overshot is determined, the power supply of the vehicle system 1 may be determined as being in an abnormal state. In general, the abnormal state of the power supply may be a power state at which the memory device fails and/or loses data (e.g., consistently, and/or at an increased risk, such as a probability above a threshold level).

The control apparatus 10 may perform various management operations, based on a change in level of the power voltage (e.g., a voltage drop), for ensuring reliability of operations of the memory device 20 and the host 30. For example, a power voltage supply from the power supply 40 may be suddenly blocked and/or stop/drop. A fault, such as damage/loss of data stored in the memory device 20, may occur based on blocked/stopped/dropped power voltage. The control apparatus 10 may detect a voltage drop during the change in level of the power voltage supplied to the memory device 20 and/or the host 30. The control apparatus 10 may perform a control operation for safe maintenance of data and stabilization of the vehicle system 1 upon sudden power-off (e.g., based on the detection of the voltage drop). If a normal power voltage is supplied to the memory device 20 and the host 30, the control apparatus 10 may control the memory device 20 and the host 30 such that operations of the vehicle system 1 are recovered. Thus, the control apparatus 10 may be designed to be able to perform an operation even if a voltage drop or a voltage rise occurs in the vehicle system 1.

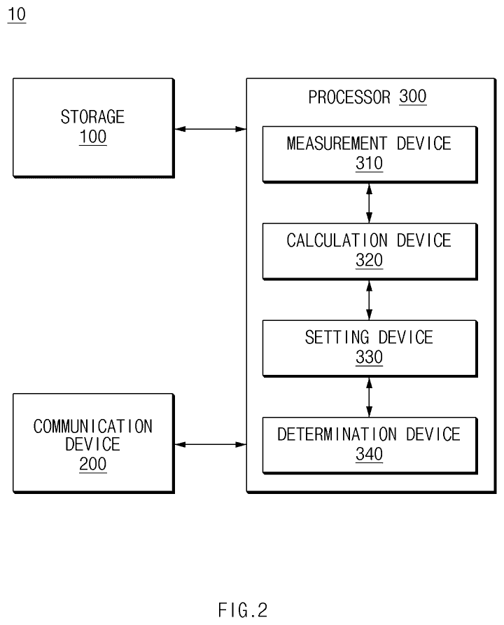

The control apparatus 10 will be described in detail below with reference to FIGS. 2 to 7.

The memory device 20 may receive and/or store voltage drop information indicating whether a voltage drop occurs in the power voltage (e.g., while operations of the memory device 20 and the host 30 are performed). For example, the memory device 20 may receive (e.g., from a sensor measuring voltage supplied by the power supply 40) and/or store the voltage drop information (e.g., as a fault code). If the voltage drop is detected in the vehicle system 1 (e.g., based on information stored in and/or received from the memory device 20 and/or host 30), the vehicle system 1 may output (e.g., via an interface to a user) a notification and/or a fault code corresponding to the voltage drop information stored in the memory device 20.

Furthermore, the memory device 20 may store state information indicating an operation state upon the voltage drop in the memory device 20 and the host 30 by means of the control apparatus 10. Thus, if the normal power voltage is supplied again after the voltage drop occurs, the memory device 20 may update the stored state information based on voltage fluctuation information.

The memory device 20 may be manufactured as anyone of various types of storage devices according to a host interface which may be/comprise a communication scheme/device for interfacing with the host 30. For example, the storage device 10 may be configured as any one of various types of storage devices, such as a solid state drive (SSD), a multimedia card in the form of an MMC, an eMMC, an RS-MMC, or a micro-MMC, a secure digital card in the form of SD, mini-SD, or micro-SD, a universal storage bus (USB) storage device, a universal flash storage (UFS) device, a storage device in the form of a personal computer memory card international association (PCMCIA) card, a storage device in the form of a peripheral component interconnection (PCI) card, a storage device in the form of a PCI-express (PCI-E) card, a compact flash (CF) card, a smart media card, and a memory stick.

The memory device 20 may be/comprise a double data rate synchronous dynamic random access memory (DDR SDRAM), a low power double data rate4 (LPDDR4) SDRAM, a graphics double data rate (GDDR) SDRAM, a low power DDR (LPDDR), a rambus dynamic random access memory (RDRAM), a NAND flash memory, a vertical NAND flash memory, a NOR flash memory, a resistive random access memory (RRAM), a phase-change memory (PRAM), a magnetoresistive random access memory (MRAM), a ferroelectric random access memory (FRAM), a spin transfer torque random access memory (STT-RAM), or the like.

The host 30 may comprise, for example and without limitation, a device for controlling the moving system 50. The host 30 may be able to control the vehicle system 1 and/or one or more components of the vehicle system 1. For example, the host 30 may be a device for controlling (e.g., at least one or more components of) a mobile phone, a smartphone, a laptop computer, a desktop computer, a game console, a household appliance (e.g., a TV, a washing machine, a drying machine, an air conditioner, or the like), or the like, as well as an electric vehicle system or an in-vehicle infotainment system.

The host 30 may communicate with the memory device 20 and the control apparatus 10. The host 30 may communicate using at least one of various communication schemes, such as a controller area network (CAN), a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), universal flash storage (UFS), a secure digital (SD), a multimedia card (MMC), an embedded MMC (eMMC), a dual in-line memory module (DIMM), a registered DIMM (RDIMM), and a load reduced DIMM (LRDIMM).

The moving system 50 may be controlled by the host 30. The moving system 50 may be/comprise a system for managing/controlling an operation of the actuator(s) 51 provided in a moveable component of the vehicle (e.g., a sunroof, a power tailgate, a power door, a power window, or the like) of a vehicle. For example, if the voltage drop occurs in the vehicle system 1, the memory device 20 may store an operation state of the actuator(s) 51 by means of the control apparatus 10. The control apparatus 10 may also, or alternatively, control the host 30 to stop some actuators 51. The control apparatus 10 may stop an operation of a device in which risk is able to occur if the vehicle suddenly stops. If the normal power voltage is supplied to the vehicle system 1 again, the actuator(s) 51 may recover the operation state stored in the memory device 20 by means of the control apparatus 10.

As described herein, the control apparatus 10 may measure, or receive (from a voltage sensor) a measurement of, a voltage supplied to the memory device 20. The control apparatus 10 determine a state of power supply (e.g., a state of the power supply and/or a state of power being supplied to the memory device 20). If power supplied to an electronic device is not smooth, the control apparatus 10 may control the power supply and/or electronic device to stabilize the power supply.

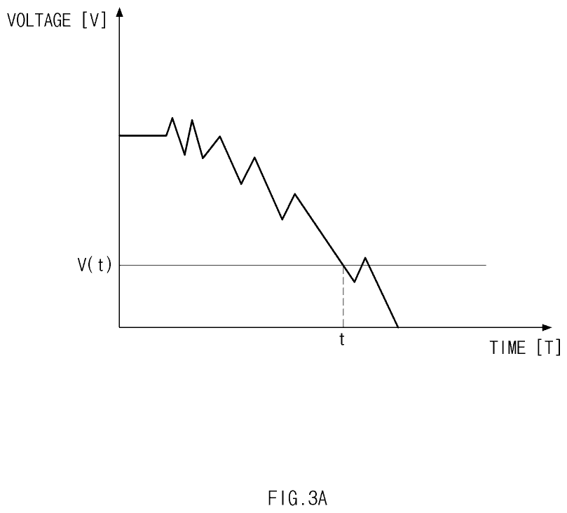

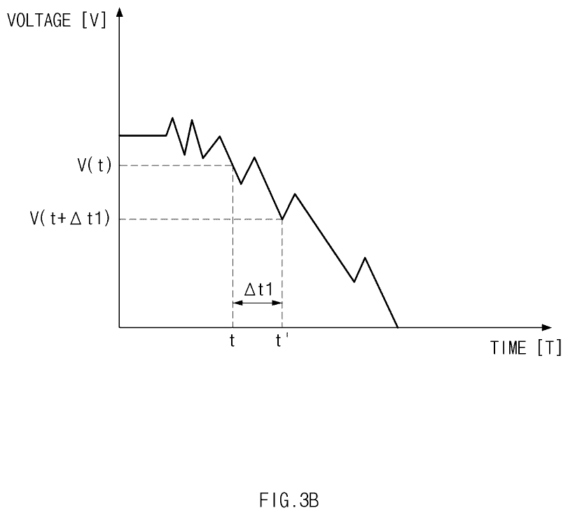

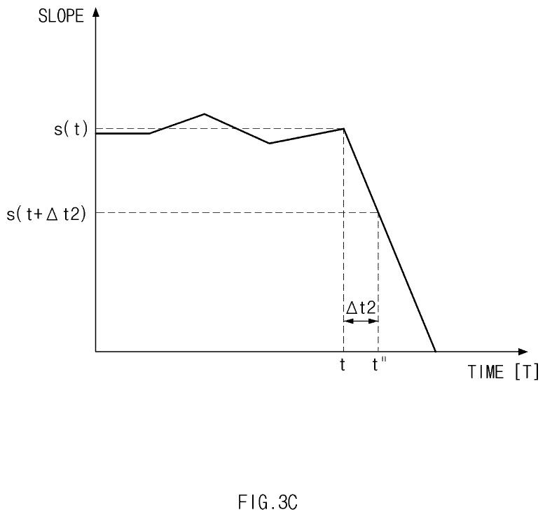

FIG. 2 is a block diagram of a control apparatus 10 based on a voltage drop according to an example of the disclosure. FIGS. 3A to 3C are an example of describing an operation of a processor 300 according to an example of the present disclosure.

Referring to FIG. 2, a control apparatus 10 may include storage 100, a communication device 200, and a processor 300.

The storage 100 may store at least one instruction of the processor 300. Herein, the storage 100 may be a device independent of memory device 20 (e.g., of FIG. 1) and/or may be included in the memory device 20.

The storage 100 may store all pieces of data performed by a measurement device 310, a calculation device 320, a setting device 330, and a determination device 340 of the processor 300.

The communication device 200 may communicate with a host 30 and the memory device 20.

The communication device 200 may support at least one of various communication schemes, such as a controller area network (CAN), a universal serial bus (USB), a serial AT attachment (SATA), a serial attached SCSI(SAS), a high speed interchip (HSIC), a small computer system interface (SCSI), a peripheral component interconnection (PCI), a PCI express (PCIe), a nonvolatile memory express (NVMe), universal flash storage (UFS), a secure digital (SD), a multimedia card (MMC), an embedded MMC (eMMC), a dual in-line memory module (DIMM), a registered DIMM (RDIMM), and a load reduced DIMM (LRDIMM).

The processor 300 may determine a state of power supply (e.g., if a voltage applied to the memory device 20 drops). The processor 300 may control operations of the memory device 20 and/or the host 30 based on the determined state of power supply.

In an example, the processor 300 may include the measurement device 310, the calculation device 320, the setting device 330, and the determination device 340. Also, or alternatively, the measurement device 310 (e.g., voltage and/or power sensor) may be separate from the processor 300 and communicate with the processor 300 via a measurement device interface of the processor 300, for example.

The measurement device 310 (e.g., voltage sensor and/or power sensor and/or interface with a voltage sensor and/or power sensor) may measure a voltage applied to the memory device 20. For example, the measurement device 310 may measure a level of the voltage applied to the memory device 20 (e.g., in real time). Also, or alternatively, the measurement device 310 may measure/determine a level of the voltage applied to the memory device 20 depending on a predetermined period/interval and/or based on a trigger event (e.g., powering on of the vehicle system 1 or one or more components thereof, etc.).

The measurement device 310 may be connected to a board on which the memory device 20 is located to measure the voltage applied to the memory device 20. Alternatively, the measurement device 310 may receive information about the level of the voltage detected by a sensor connected to the power supply to the memory device 20.

Referring to FIGS. 3A to 3C, the calculation device 320 may calculate a voltage value V(t), a voltage drop slope S(t) and a slope change rate dSt based on the level of the voltage, which is measured by the measurement device 310.

FIG. 3A is a graph of a voltage over time, which is received from the measurement device 310.

The calculation device 320 may calculate/track/receive the voltage value V(t) over time (e.g., as in the voltage over time graph in FIG. 3A) and/or compare the voltage value V(t) with a threshold voltage value(s). If the determination device 340 determines that the voltage value V(t) is less than or equal to a first threshold T1, the calculation device 320 may calculate the voltage drop slope S(t) corresponding to the time at which the voltage dropped to/below the first threshold T1. The voltage drop slope S(t) may be a slope of a voltage drop, e.g., a negative slope of the voltage value V(t) graph. If the determination device 340 determines that a voltage drop occurs (e.g., the voltage value V(t) is equal to or below the first threshold T1), the calculation device 320 may calculate the voltage drop slope S(t).

Herein, the first threshold T1 may be a predetermined voltage value. The first threshold T1 may vary with a vehicle type, a system size, a battery size, a magnitude of supplied power, a type of the memory device 20, a type of the host 30, or the like. The first threshold T1 may be relative to an average power usage of the memory device 20 (e.g., over a given time, such as an average over a lifetime of the memory device 20, over the past day of the memory device, over the past hour, over the past minute, etc.). The first threshold T1 may be a voltage value determined to correspond to and/or correlate with power supply of a vehicle system 1 functioning abnormally. For example, if the measured voltage value is less than or equal to the first threshold T1, the determination device 340 may determine that a voltage drop occurred. However, although the measured voltage value is less than or equal to the first threshold T1, the determination device 340 may not conclude that power supply of the vehicle system 1 is in the abnormal state. The calculation device 320 may calculate the voltage drop slope S(t) and/or the slope change rate dS(t).

The calculation device 320 may calculate the voltage drop slope S(t) based on the voltage V(t) over time. If the determination device 340 determines that the voltage drop slope S(t) (e.g., in a graph, as in FIG. 3A) is greater than or equal to a second threshold T2 (e.g., if the absolute value of the slope), the calculation device 320 may calculate the slope change rate dS(t).

Referring to FIG. 3B, the calculation device 320 may calculate a voltage drop slope S(t) during a first time Δt1. Herein, the first time Δt1 may be a predetermined time interval (e.g., comprising and/or based on the time point t). For example, the first time Δt1 may be a time interval between a time point t′ and a time point t (e.g., at which the voltage value V(t) was determined equal to or less than first threshold T1).

The voltage drop slope S(t) may be a value obtained by dividing a difference between the voltage value V(t) (at the time point t) and a voltage value V(t+Δt1) (at the time point t′=t+Δt1) by the first time Δt1. The voltage drop slope S(t) may be represented as |(V(t)−V(t+Δt1))/Δt1|.

The second threshold T2 may be a predetermined voltage drop slope. The second threshold T2 may vary based on a vehicle type, a system size, a battery size, a magnitude of supplied power, a type of the memory device 20, a type of the host 30, or the like. The second threshold T2 may be a voltage drop slope determined to correspond to abnormal functioning of the power supply of the vehicle system 1. For example, if the voltage drop slope of the measured voltage value is greater than or equal to the second threshold T2, the determination device 340 may determine that power supply is not smooth (e.g., is sharp/steep) by the voltage drop. Although the calculated voltage drop slope is greater than or equal to the second threshold T2, the determination device 340 may not conclude that power supply of the vehicle system 1 is in the abnormal state. The calculation device 320 may additionally calculate the slope change rate dS(t).

Referring to FIG. 3C, the calculation device 320 may calculate the slope change rate dS(t) based on the voltage drop slope S(t) over time (e.g., as in a graph, such as in FIG. 3B).

The calculation device 320 may calculate a slope change rate dS(t) during/over a second time Δt2. Herein, the second time Δt2 may be a predetermined time interval(e.g., comprising and/or based on the time point t). For example, the second time Δt2 may be a time interval between a time point t″ and the time point t.

The slope change rate dS(t) may be a value obtained by dividing a difference value between the voltage drop slope S(t) at the time point t and a voltage drop slope S(t+Δt2) at the time point t″ by the second time Δt2. The slope change rate dS(t) may be represented as |(S(t)−S((t+Δt2))/Δt2|.

The calculation device 320 may transmit the calculated slope change rate dS(t) to the determination device 340. The determination device 340 may determine whether the slope change rate dS(t) is greater than or equal to a third threshold T3.

The third threshold T3 may be a change rate of the predetermined voltage drop slope. The third threshold T3 may vary based on a vehicle type, a system size, a battery size, a magnitude of supplied power, a type of the memory device 20, a type of the host 30, or the like. The third threshold T3 may be a change rate of the voltage drop slope determined to correspond to abnormal operation of the power supply of the vehicle system 1. For example, if the slope change rate of the measured voltage value is greater than or equal to the third threshold T3, the determination device 340 may determine the power supply of the vehicle system 1 as being in the abnormal state.

Referring again to FIG. 2, the setting device 330 may set at least one threshold corresponding to the voltage value V(t), the voltage drop slope S(t) and/or the slope change rate dS(t). The threshold corresponding to the voltage value V(t) may be the first threshold T1. The threshold corresponding to the voltage drop slope S(t) may be the second threshold T2. The threshold corresponding to the slope change rate dS(t) may be the third threshold T3. For example, the first threshold T1, the second threshold T2, and the third threshold T3 may vary based on a vehicle type, a system size, a battery size, a magnitude of supplied power, a type of the memory device 20, a type of the host 30, or the like.

In an example, the first threshold T1, the second threshold T2, and the third threshold T3 may be preset by a manufacturer (e.g., may be input to the setting device 330 upon manufacture). For example, the first threshold T1, the second threshold T2, and the third threshold T3 may be values set in/via a test process of the vehicle system 1. The test may be performed in a state in which a battery and/or a power connector of the vehicle is removed. Also, or alternatively, an operation of decreasing or increasing a level of an input voltage in the vehicle system 1 and the memory device 20 may be performed in the test. The test may be performed in various environments in which the power supply of the vehicle is in an abnormal state (e.g., not providing power and/or providing controlled reduced power). By repeating the test, thresholds for the voltage value V(t), the voltage drop slope S(t) and the slope change rate dS(t), which cause a problem in the vehicle system 1 and/or the memory device 20, may be extracted/determined. The first threshold T1, the second threshold T2, and the third threshold T3 may be input to the setting device 330 after being determined via the repetition of the above-mentioned test.

For another example, at least one parameter among the voltage value V(t), the voltage drop slope S(t) or the slope change rate dS(t) may be selected in the test process. The selected at least one parameter may be fixed and the unselected remaining parameters may be adjusted. The unselected parameter(s) may be adjusted, in various environments in which the power supply of the vehicle is in the abnormal state (e.g., to determine ranges of the unselected parameter(s) corresponding to an abnormal state). The above-mentioned test process may be repeated, for example with different values of the fixed parameter. Based on the test result, the setting device 330 may set the first threshold T1, the second threshold T2, and the third threshold T3 for a voltage drop which causes a problem in the vehicle system 1 and the memory device 20.

The setting device 330 may calculate the first threshold T1, the second threshold T2, and the third threshold T3 using a learning model. For example, the setting device 330 may train the learning model using the above-mentioned test results and/or historical data (e.g., corresponding to normal and abnormal functioning of the memory device) to generate a prediction model which outputs the first threshold T1, the second threshold T2, and the third threshold T3. The setting device 330 may input data of the vehicle system 1 to the prediction model generated from the learning model. The prediction model may output the first threshold T1, the second threshold T2, and the third threshold T3 via its calculation. Herein, the learning model may include at least one of a convolutional neural network (CNN), a recurrent neural network (RNN), or machine learning.

The determination device 340 may compare the calculated result of the calculation device 320 with the threshold to determine a state of power supply.

In an example, the determination device 340 may receive the voltage value V(t) from the measurement device 310 or the calculation device 320. The determination device 340 may receive the first threshold T1 from the setting device 330. The determination device 340 may compare the voltage value V(t) with the first threshold T1. If the determination device 340 determines that the voltage value V(t) is less than or equal to the first threshold T1, the calculation device 320 may calculate the voltage drop slope S(t) during the first time Δt1. If determining that the voltage value V(t) is greater than the first threshold T1, the determination device 340 may determine the power supply as being in a normal state.

The determination device 340 may receive the calculated voltage drop slopeS(t) from the calculation device 320. The determination device 340 may receive the second threshold T2 from the setting device 330. The determination device 340 may compare the voltage drop slope S(t) with the second threshold T2. If the determination device 340 determines that the voltage drop slope S(t) is greater than or equal to the second threshold T2, the calculation device 320 may calculate the slope change rate dS(t) during the second time Δt2. If determining that the voltage drop slope S(t) is less than the second threshold T2, the determination device 340 may determine the power supply as being in the normal state.

The determination device 340 may receive the calculated slope change rate dS(t) from the calculation device 320. The determination device 340 may receive the third threshold T3 from the setting device 330. The determination device 340 may compare the slope change rate dS(t) with the third threshold T3. For example, if determining that the slope change rate dS(t) is greater than or equal to the third threshold T3, the determination device 340 may determine the power supply as being in the abnormal state. If determining that the slope change rate dS(t) is less than the third threshold T3, the determination device 340 may determine the power supply as being in the normal state.

If the power supply is determined to be in an abnormal state, the determination device 340 may control the host 30 to generate an operation control signal in relation to the real-time control signal of the host 30. For example, when an actuator 51 is operating based on a real-time control signal output by the host 30, the determination device 340 may cause the host 30 to generate an operation control signal that stops, reverses, or maintains the actuator's operation. Additionally, the determination device 340 may transmit a control signal to the host 30 to instruct it to generate the operation control signal in response to, or in consideration of, the real-time control signal. For example, the host 30 may control some actuators 51 to stop. The determination device 340 may control the host 30 to stop an operation of a device in which risk is able to occur if the vehicle suddenly stops.

The determination device 340 may control the memory device 20 to store the operation control signal. For example, if the voltage drop occurs in the vehicle system 1, the memory device 20 may store an operation state of the actuator 51 provided in the above-mentioned device (e.g., by means of the determination device 340). If the normal power voltage is supplied to the vehicle system 1, the actuator 51 may recover the operation state stored in the memory device 20 (e.g., by means of the determination device 340).

In another example, the setting device 330 may assign a weight (e.g., respective weights) to each of the first threshold T1, the second threshold T2, and the third threshold T3. Respective weights a, J, and y may be preset via the above-mentioned test process. For example, if the slope change rate dS(t) is greater than or equal to the third threshold T3, there is a high possibility that power supply will be determined as being in the abnormal state (e.g., slope change rate dS(t) may correlate most strongly with the abnormal state—such a power state at which the memory device fails and/or loses data). Therefore, the setting device 330 may assign the largest weight to the third threshold T3. Although the measured voltage value is less than or equal to the first threshold T1, the power supply of the vehicle system 1 may not be determined as being in the abnormal state. Therefore, the setting device 330 may assign the smallest weight to the third threshold T1.

The calculation device 320 may receive voltage data over time from the measurement device 310. The calculation device 320 may receive the first threshold T1 from the setting device 330. The calculation device 320 may calculate a first value obtained by dividing the first threshold T1 by the voltage value V(t). The first value may be represented as T1/V(t).

The calculation device 320 may calculate the voltage drop slope S(t) based on the voltage graph over time. The calculation device 320 may receive the second threshold T2 from the setting device 330. The calculation device 320 may calculate a second value obtained by dividing the second threshold T2 by the voltage drop slope S(t) The second value may be represented as T2/S(t).

The calculation device 320 may calculate the slope change rate dS(t) based on the graph for the voltage drop slope S(t) over time. The calculation device 320 may receive the third threshold T3 from the setting device 330. The calculation device 320 may calculate a third value obtained by dividing the third threshold T3 by the slope change rate dS(t). The third value may be represented as T3/dS(t).

The calculation device 320 may also receive the weight from the setting device 330. The calculation device 320 may multiply each of the first value, the second value, and the third value by the weight. The calculation device 320 may multiply the first value T1/V(t) by the weight α, may multiply the second value T2/S(t) by the weight β, and may multiply the third value T3/dS(t) by the weight γ. The calculation device 320 may calculate a fourth value obtained by adding all the multiplied values. That is, the fourth value may be

$$α \frac{T 1}{V t} + β \frac{T 2}{St} + γ \frac{T 3}{dSt} .$$

The determination device 340 may receive the fourth value calculated by the calculation device 320. Herein, the fourth threshold T4 may be extracted via the same test process as the first to third thresholds T1 to T3. In an example, the fourth threshold T4 preset by a manufacturer may be input to the setting device 330. For example, the fourth threshold T4 may be a value set in the test process of the vehicle system 1. The test may be performed in a state in which a battery and/or a power connector of the vehicle is removed. Alternatively, an operation of decreasing or increasing a level of an input voltage in the vehicle system 1 and the memory device 20 may be performed in the test. The test may be performed in various environments in which the power supply of the vehicle is in the abnormal state. By repeating the test, the fourth threshold T4 in which causes a problem in the vehicle system 1 and the memory device 20 may be input to the setting device 330.

The setting device 330 may calculate the fourth threshold T4 using the learning model. For example, the setting device 330 may train the learning model using the above-mentioned test result to generate a prediction model which outputs the fourth threshold T4. The setting device 330 may input data of the vehicle system 1 to the prediction model generated from the learning model. The prediction model may output the fourth threshold T4 via its calculation.

The determination device 340 may compare the fourth value with the fourth threshold T4. For example, if determining that the fourth value is greater than or equal to the fourth threshold T4, the determination device 340 may determine the power supply as being in the abnormal state. If determining that the fourth value is less than the fourth threshold T4, the determination device 340 may determine the power supply as being in the normal state.

As described herein, the control apparatus 10 based on the voltage drop according to the present disclosure may measure a change in voltage supplied to the storage device to prevent damage of data stored in the memory.

Although power may be disrupted (e.g., suddenly not supplied) to an electronic device, the control apparatus 10 may store data of the memory to improve reliability of the electronic device. The control apparatus 10 may quickly determine that the power supply is in the abnormal state to ensure a time for controlling the memory storage and the system/host.

Furthermore, although power is not suddenly supplied to the electronic device, the control apparatus 10 may maintain or immediately recover an operation of the electronic device to improve reliability of the electronic device.

For example, if a problem occurs in power supply in an electric vehicle including the control apparatus 10 according to the present disclosure, data of the electric vehicle may be stored and the operation of the electric vehicle may be maintained and/or immediately recovered. Therefore, reliability of the electric vehicle may be improved. For another example, the control apparatus 10 according to the present disclosure may be provided in an electronic device installed in an area where a power outage frequently occurs. Therefore, although the power outage occurs, data of the electronic device may be stored and the operation of the electronic device may be maintained and/or immediately recovered.

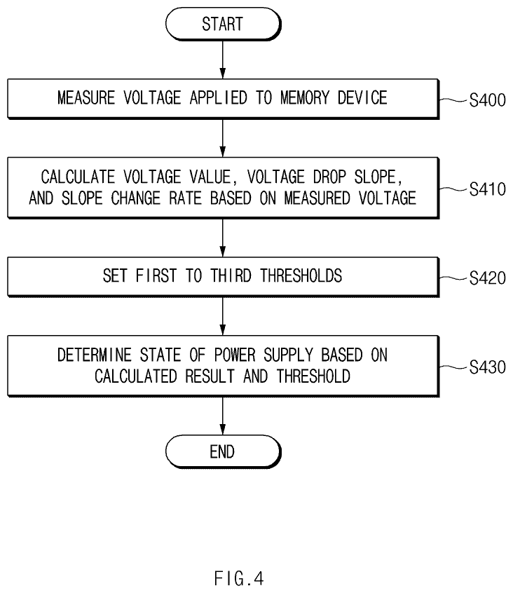

FIG. 4 is a flowchart for describing a control method based on a voltage drop according to example of the present disclosure. A control method based on a voltage drop, shown in FIGS. 4 to 7, may be a control method performed by a control apparatus 10 in FIGS. 1 and 2. For convenience, FIGS. 4 to 7 are described by way of an example in which the steps are performed by a processor circuit (e.g., of the control apparatus 10). One, some, or all steps of the example method of FIGS. 4 to 7, or portions thereof, may be performed by one or more other circuits. One or some, steps of the example method of FIGS. 4 to 7 may be omitted, performed in other orders, and/or otherwise modified, and/or one or more additional steps may be added.

Referring to FIG. 4, in S400, a voltage applied to a memory device may be measured/received (e.g., by a measurement device and/or a sensor, such as measured by the sensor and received, from the sensor, by the measurement device of the control apparatus). For example, a measurement device may measure/receive/determine a level of the voltage applied/supplied to the memory device in real time. Also, or alternatively, the measurement device may measure a level of the voltage applied to the memory device periodically (e.g., depending on a predetermined certain period).

In S410, a voltage value, a voltage drop slope, and a slope change rate may be calculated based on the measured voltage. For example, a calculation device may calculate the voltage value, the voltage drop slope, and the slope change rate based on the measured level of the voltage.

In an example, the calculation device may calculate a voltage value V(t) based on a voltage graph over time. The calculation device may calculate a voltage drop slope based on the voltage graph over time. The calculation device may calculate a voltage drop slope S(t) during a first time Δt1. Herein, the first time Δt1 may be a predetermined time interval (e.g., comprising and/or based on the time point t). For example, the first time Δt1 may be a time interval between a time point t′ and a time point t.

The voltage drop slope S(t) may be a value obtained by dividing a difference value between the voltage value V(t) at the time point t and a voltage value V(t+Δt1) at the time point t′ by the first time Δt1. The voltage drop slope S(t) may be represented as |(V(t)−V((t+Δt1))/Δt1|.

The calculation device may calculate (e.g., determine, herein) a slope change rate dS(t) based on the graph for the voltage drop slope S(t) over time.

The calculation device may calculate a slope change rate dS(t) during a second time Δt2. Herein, the second time Δt2 may be a predetermined time interval (e.g., comprising and/or based on the time point t). For example, the second time Δt2 may be a time interval between a time point t″ and the time point t.

The slope change rate dS(t) may be a value obtained by dividing a difference value between the voltage drop slope S(t) at the time point t and a voltage drop slope S(t+Δt2) at the time point t″ by the second time Δt2. The slope change rate dS(t) may be represented as |(S(t)−S((t+Δt2))/Δt2|.

In S420, the first to third thresholds may be set. For example, a setting device may set at least one threshold corresponding to at least one of the voltage value, the voltage drop slope, and the slope change rate. Herein, the threshold corresponding to the voltage value may be a first threshold. The threshold corresponding to the voltage drop slope may be a second threshold. The threshold corresponding to the slope change rate may be a third threshold. For example, the first threshold, the second threshold, and the third threshold may vary with a vehicle type, a system size, a battery size, a magnitude of supplied power, a type of the memory device, a type of the host, or the like.

In an example, the calculation device may calculate/determine/monitor a voltage value over time (e.g., based on the voltage graph over time). If the determination device determines that the voltage value is less than or equal to the first threshold, the calculation device may calculate a voltage drop slope. If the determination device determines that a voltage drop occurs, the calculation device may calculate the voltage drop slope.

The calculation device may calculate/determine/monitor the voltage drop slope over time (e.g., based on the voltage graph over time). If the determination device determines that the voltage drop slope is greater than or equal to the second threshold, the calculation device may calculate a slope change rate.

The calculation device may calculate/determine/monitor a slope change rate over time based on a voltage drop slope graph over time. The calculation device may transmit the calculated slope change rate to the determination device. The determination device may determine whether the slope change rate is greater than or equal to the third threshold.

In S430, a state of power supply may be determined based on the result(s) (e.g., the voltage value, the voltage drop slope, or the slope change rate) and the threshold(s). For example, the determination device may compare the result of the calculation device with the threshold to determine a state of power supply.

If the power supply is determined as in an abnormal state, the determination device may control the host to generate an operation control signal (e.g., based on/via a real-time control signal to the host 30). For example, the host may be controlled to stop some actuators. The determination device may stop an operation of a device in which risk is able to occur if a vehicle suddenly stops.

The determination device may control the memory device to store the operation control signal. For example, if a voltage drop occurs in a vehicle system, the memory device may store an operation state of the actuator provided in the above-mentioned device by means of the determination device. If a normal power voltage is supplied to the vehicle system again, the actuator may recover the operation state stored in the memory device by means of the determination device.

As described herein, the control method based on the voltage drop according to the present disclosure may be to measure the voltage supplied to the memory device and determine the state of the power supply. Furthermore, the control method may be to control the system to be stabilized, if the power supply to the electronic device is not smooth.

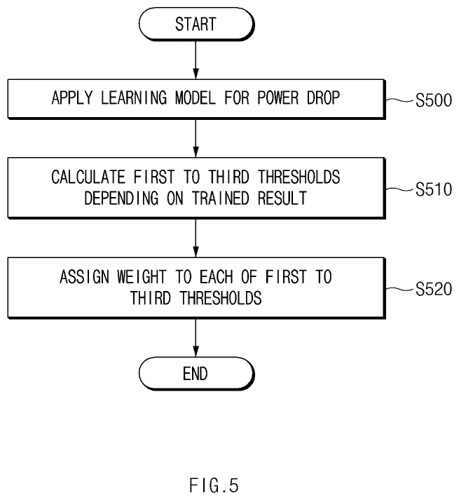

FIG. 5 is a flowchart for describing in detail a control method based on a voltage drop according to example of the present disclosure.

Referring to FIG. 5, in S500, a learning model for a power drop may be applied. Herein, the learning model may include at least one of a convolutional neural network (CNN), a recurrent neural network (RNN), or machine learning.

In S510, first to third thresholds may be calculated according to the trained result. For example, a setting device may train the learning model using the test results disclosed herein to generate a prediction model that outputs the first threshold, the second threshold, and the third threshold. The setting device may input data of a vehicle system to the prediction model generated from the learning model. The prediction model may output the first threshold, the second threshold, and the third threshold via its calculation.

In S520, respective weights may be assigned to each of the first to third thresholds. For example, the setting device may assign the weights to each of the first threshold, the second threshold, and the third threshold. In detail, if the slope change rate is greater than or equal to the third threshold, there is a high possibility that power supply will be determined as being in an abnormal state. Therefore, the setting device may assign the largest weight to the third threshold. On the other hand, although the measured voltage value is less than or equal to the first threshold, the power supply of the vehicle system may not necessarily be determined as being in the abnormal state. Therefore, the setting device may assign the smallest weight to the first threshold.

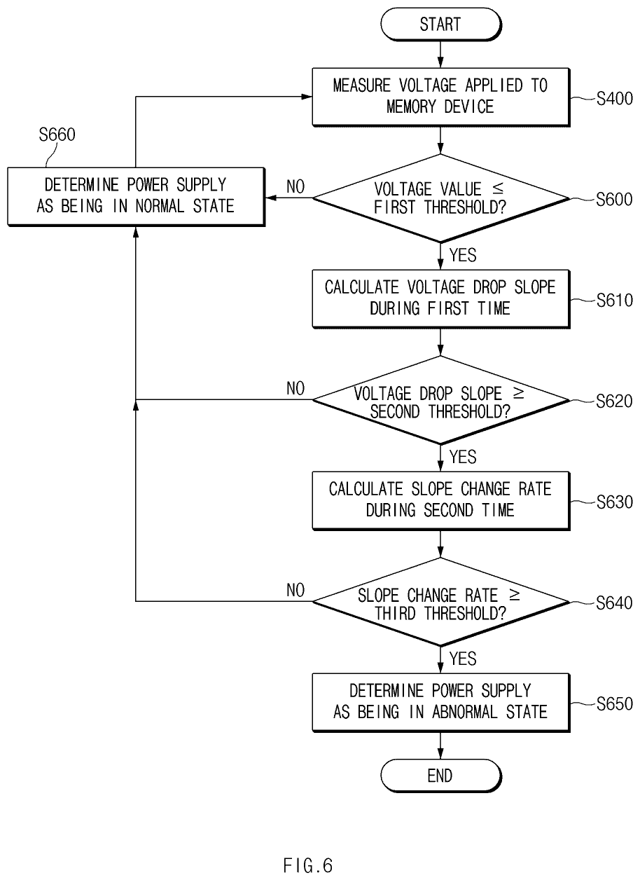

FIG. 6 is a flowchart for describing in detail a control method based on a voltage drop according to example of the present disclosure.

Referring to FIG. 6, in S400, a voltage applied to a memory device may be measured. For example, a measurement device may measure a level of the voltage applied to the memory device in real time. Also, or alternatively, the measurement device may measure a level of the voltage applied to the memory device depending on a predetermined certain period.

In S600, it may be determined whether a voltage value is less than or equal to a first threshold. For example, a determination device may compare the voltage value with the first threshold.

If the voltage value is greater than the first threshold, in S660, power supply may be determined as being in a normal state. For example, if determining that the voltage value is greater than the first threshold, the determination device may determine the power supply as being in the normal state.

If the voltage value is less than or equal to the first threshold, in S610, a voltage drop slope during a first time may be calculated. For example, if the determination device determines that the voltage value is less than or equal to the first threshold, a calculation device may calculate the voltage drop slope during the first time.

In S620, it may be determined whether the voltage drop slope is greater than or equal to a second threshold. For example, the determination device may compare the voltage drop slope with the second threshold.

If the voltage drop slope is less than the second threshold, in S660, the power supply may be determined as being in the normal state. For example, if determining that the voltage drop slope is less than the second threshold, the determination device may determine the power supply as being in the normal state.

If the voltage drop slope is greater than or equal to the second threshold, in S630, a slope change rate during a second time may be calculated. For example, if the determination device determines that the voltage drop slope is greater than or equal to the second threshold, the calculation device may calculate the slope change rate during the second time.

In S640, it may be determined whether the slope change rate is greater than or equal to a third threshold. For example, the determination device may compare the slope change rate with the third threshold.

If the slope change rate is less than the third threshold, in S660, the power supply may be determined as being in the normal state. For example, if determining that the slope change rate is less than the third threshold, the determination device may determine the power supply as being in the normal state.

If the slope change rate is greater than or equal to the third threshold, in S650, power supply may be determined as being in the abnormal state. For example, if determining that the slope change rate is greater than or equal to the third threshold, the determination device may determine the power supply as being in the abnormal state.

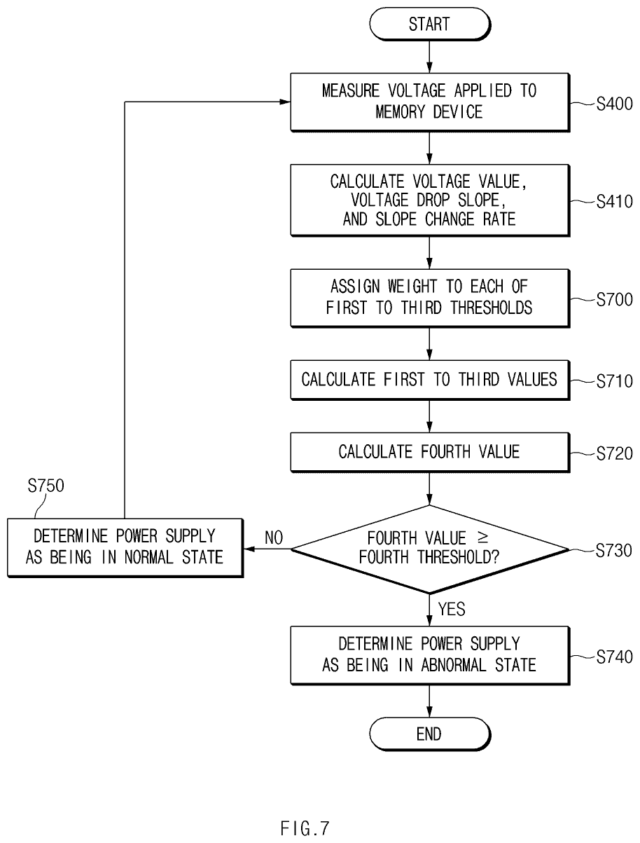

FIG. 7 is a flowchart for describing in detail a control method based on a voltage drop according to example of the present disclosure.

Referring to FIG. 7, in S400, a voltage applied to a memory device may be measured. For example, as disclosed herein, a measurement device may measure a level of the voltage applied to the memory device in real time. Also, or alternatively, the measurement device may measure a level of the voltage applied to the memory device depending on a predetermined certain period.

In S410, a voltage value, a voltage drop slope, and a slope change rate may be calculated based on the measured voltage. For example, a calculation device may calculate the voltage value, the voltage drop slope, and the slope change rate based on the measured level of the voltage.

In S700, respective weights may be assigned to each of the first to third thresholds. For example, a setting device may assign the weights to the first threshold, the second threshold, and the third threshold. If the slope change rate is greater than or equal to the third threshold, there is a high possibility that power supply will be determined as being in an abnormal state. Therefore, the setting device may assign the largest weight to the third threshold. Even if the measured voltage value is less than or equal to the first threshold, the power supply of the vehicle system may not be determined as being in the abnormal state. Therefore, the setting device may assign the smallest weight to the first threshold.

In S710, first to third values may be calculated. For example, the calculation device may calculate the first value obtained by dividing the first threshold by the voltage value. The first value may be represented as T1N(t). The calculation device may calculate the second value obtained by dividing the second threshold by the voltage drop slope. The second value may be represented as T2/S(t). The calculation device may calculate the third value obtained by dividing the third threshold by the slope change rate. The third value may be represented as T3/dS(t).

In S720, a fourth value may be calculated. For example, the calculation device may multiply each of the first value, the second value, and the third value by respective weights. The calculation device may multiply the first value T1/V(t) by a weight α, may multiply the second value T2/S(t) by a weight β, and may multiply the third value T3/dS(t) by a weight γ. The calculation device may calculate the fourth value obtained by adding all the multiplied values. That is, the fourth value may be

$$α \frac{T 1}{V t} + β \frac{T 2}{St} + γ \frac{T 3}{dSt} .$$

In S730, it may be determined whether the fourth value is greater than or equal to a fourth threshold. For example, the determination device may receive the fourth value calculated by the calculation device. Herein, the fourth threshold may be extracted via the same process as the first to third thresholds. That is, the setting device may preset the fourth threshold. The determination device may compare the fourth value with the fourth threshold.

If it is determined that the fourth value is greater than or equal to the fourth threshold, in S740, power supply may be determined as being in an abnormal state. For example, based on determining that the fourth value is greater than or equal to the fourth threshold, the determination device may determine the power supply as being in the abnormal state.

If it is determined that the fourth value is less than the fourth threshold, in S750, the power supply may be determined as being in a normal state. For example, if determining that the fourth value is less than the fourth threshold, the determination device may determine the power supply as being in the normal state.

As described above, the control method based on the voltage drop according to the present disclosure may allow for measuring the change in voltage supplied to the storage device to prevent damage of data stored in the memory.

Furthermore, the control method may be to store data of the memory to improve reliability of the electronic device, even if power supplied to the electronic device is disrupted (e.g., suddenly stopped/reduced). The control method may be to quickly determine that the power supply is in the abnormal state to ensure a time for controlling the memory storage and the system.

Furthermore, the control method may be to maintain and/or immediately recover an operation of the electronic device to improve reliability of the electronic device, even if power supplied to the electronic device is disrupted.

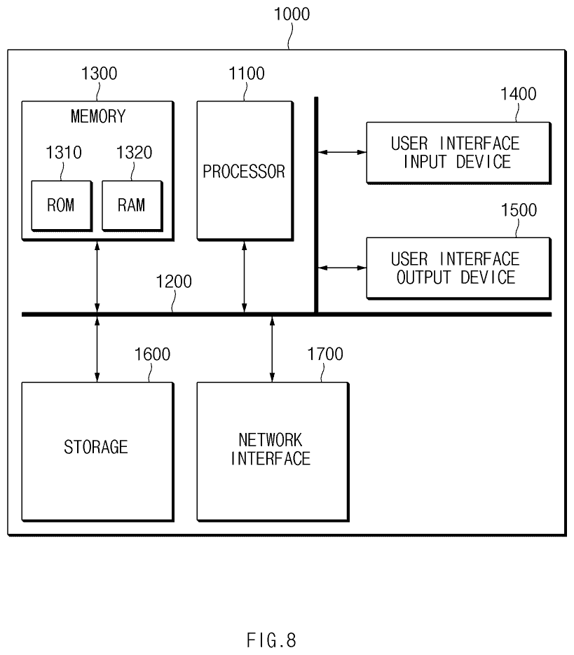

FIG. 8 is a block diagram illustrating a computing system for a control apparatus 10 based on a voltage drop according to an example of the present disclosure.

Referring to FIG. 8, a computing system 1000 may include at least one processor 1100, a memory 1300, a user interface input device 1400, a user interface output device 1500, a storage 1600, and a network interface 1700, which are connected with each other via a bus 1200.

The processor 1100 may be/comprise a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with the examples disclosed in the specification may be directly implemented with a hardware module, a software module, or a combination of the hardware module and the software module, which is executed by the processor 1100. The software module may reside on a storage medium (i.e., the memory 1300 and/or the storage module 1600) such as a RAM, a flash memory, a ROM, an EPROM, an EEPROM, a register, a hard disc, a removable disk, and a CD-ROM.

The exemplary storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The user interface input device 1400 may include an input device that receive a user input.

For example, the input device may receive various user inputs for setting a function of a vehicle from a user. For example, the input device may be provided as a tact switch, a joystick, a push switch, a slide switch, a toggle switch, a micro switch, or a touch screen. Furthermore, the input device may include a microphone for receiving a voice input of the user.

The user interface output device 1500 may include a display for displaying various pieces of information associated with driving of the vehicle and/or a function of the vehicle and a speaker for outputting various sounds associated with the driving of the vehicle and/or the function of the vehicle.

Herein, the display provides a user interface for allowing a passenger and the vehicle to interact with each other. For example, the display may include a liquid crystal display (LCD) panel and/or a light emitting diode (LED).

The network interface 1700 may include along range communication and/or a short range communication module, which transmit(s) and receive(s) data with an external device (e.g., a server or a user terminal). For example, the network interface 1700 may refer to a communication module capable of performing wireless Internet communication, such as a wireless LAN (WLAN), wireless broadband (Wibro), wireless-fidelity (Wi-Fi), world interoperability for microwave access (WiMAX), or high speed downlink packet access (HSDPA).

The present disclosure provides a control apparatus for measuring a voltage applied to a memory device and determining a state of power supply and a method thereof.

The present disclosure provides a control apparatus for controlling a system to be stabilized, if power supply to an electronic device is not smooth and a method thereof.

A control apparatus based on a voltage drop may include a communication device that communicates with a host and a memory device, a processor that determines a state of power supply, if a voltage applied to the memory device drops, and controls operations of the memory device and the host based on the determined result, and storage storing at least one instruction of the processor.

In an example, the processor may include a measurement device that measures the voltage applied to the memory device, a calculation device that calculates a voltage value, a voltage drop slope, and a slope change rate based on the measured voltage, a setting device that sets at least one threshold corresponding to the voltage value, the voltage drop slope, and the slope change rate, and a determination device that determines the state of the power supply based on the calculated result and the threshold.

In an example, the setting device may set a first threshold corresponding to the voltage value, a second threshold corresponding to the voltage drop slope, and a third threshold corresponding to the slope change rate.

In an example, the setting device may assign a weight to each of the first threshold, the second threshold, and the third threshold.

In an example, the setting device may calculate the first threshold, the second threshold, and the third threshold using a learning model.

In an example, the calculation device may calculate the voltage drop slope during a first time, if the voltage value is less than or equal to the first threshold.

In an example, the calculation device may calculate the slope change rate during a second time, if the voltage drop slope is greater than or equal to the second threshold.

In an example, the determination device may determine the power supply as being in an abnormal state, if the slope change rate is greater than or equal to the third threshold.

In an example, the determination device may control the host to generate an operation control signal based on a real-time control signal of the host and may control the memory device to store the operation control signal, if determining the power supply as being in the abnormal state.

In an example, the calculation device may calculate a first value obtained by dividing the first threshold by the voltage value, a second value obtained by dividing the second threshold by the voltage drop slope, and a third value obtained by dividing the third threshold by the slope change rate, if the slope change rate is greater than or equal to the third threshold.

In an example, the calculation device may calculate a fourth value obtained by multiplying each of the first value, the second value, and the third value by the weight and adding all the multiplied results.

In an example, the determination device may determine the power supply as being in an abnormal state, if the fourth value is greater than or equal to a fourth threshold.

A control method based on a voltage drop may include communicating with a host and a memory device, determining, by a processor, a state of power supply, if a voltage applied to the memory device drops, controlling, by the processor, operations of the memory device and the host based on the determined result, and storing at least one instruction of the processor.

In another example, the determining of the state of the power supply may include measuring the voltage applied to the memory device, calculating a voltage value, a voltage drop slope, and a slope change rate based on the measured voltage, setting at least one threshold corresponding to the voltage value, the voltage drop slope, and the slope change rate, and determining the state of the power supply based on the calculated result and the threshold.

In another example, the setting of the at least one threshold may include setting a first threshold corresponding to the voltage value, a second threshold corresponding to the voltage drop slope, and a third threshold corresponding to the slope change rate.

In another example, the setting of the at least one threshold may include assigning a weight to each of the first threshold, the second threshold, and the third threshold.

In another example, the calculating may include calculating the voltage drop slope during a first time, if the voltage value is less than or equal to the first threshold.

In another example, the calculating may include calculating the slope change rate during a second time, if the voltage drop slope is greater than or equal to the second threshold.

In another example, the determining of the state of the power supply may include determining the power supply as being in an abnormal state, if the slope change rate is greater than or equal to the third threshold.

In another example, the determining of the state of the power supply may further include determining the power supply as being in the abnormal state, controlling the host to generate an operation control signal based on a real-time control signal of the host, and controlling the memory device to store the operation control signal.

The technical problems to be solved by the present disclosure are not limited to the problems mentioned herein. Other technical problems solved by the present disclosed subject matter will be clearly understood from the description by those skilled in the art to which the present disclosure pertains.

The present technology may measure a change in voltage supplied to the storage device to prevent damage of data stored in the memory.

Furthermore, the present technology may store data of the memory to improve reliability of an electronic device, even if power is not suddenly supplied to the electronic device.

Furthermore, the present technology may maintain or immediately recover an operation of the electronic device to improve reliability of the electronic device, if power is not suddenly supplied to the electronic device.

In addition, various effects ascertained directly or indirectly through the present disclosure may be provided.

Hereinabove, although the present disclosure has been described with reference to examples and the accompanying drawings, the present disclosure is not limited thereto, but may be variously modified and altered by those skilled in the art to which the present disclosure pertains without departing from the spirit and scope of the present disclosure claimed in the following claims.

Therefore, examples of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A control apparatus comprising:
a communication interface configured to communicate with a host device and a memory device associated with the host device;
a processor; and
a storage storing instructions that, when executed, configure the processor to:
receive, from a voltage sensor, an indication of a drop in a voltage being supplied to the memory device;
determine, based on the indication of the drop in the voltage, a state of a power supply supplying the voltage to the memory device; and
control, based on the determined state of the power supply, one or more operations of the memory device and the host device.

2. The control apparatus of claim 1, wherein the processor is configured to:
receive a measurement of the voltage supplied to the memory device;
determine, based on the measurement of the voltage, a voltage value, a voltage drop slope, and a slope change rate;
set at least one threshold corresponding to the voltage value, the voltage drop slope, and the slope change rate; and
determine the state of the power supply based on:
the voltage value, the voltage drop slope, and the slope change rate; and
the at least one threshold.

3. The control apparatus of claim 2, wherein the processor is configured to:
set a first threshold corresponding to the voltage value, a second threshold corresponding to the voltage drop slope, and a third threshold corresponding to the slope change rate.

4. The control apparatus of claim 3, wherein the processor is configured to:
assign a first weight to the first threshold, a second weight to the second threshold, and a third weight to the third threshold.

5. The control apparatus of claim 4, wherein the processor is configured to:
use a learning model to determine the first threshold, the second threshold, and the third threshold.

6. The control apparatus of claim 4, wherein the processor is configured to:
determine, based on the voltage value being less than or equal to the first threshold, the voltage drop slope during a first time interval.

7. The control apparatus of claim 5, wherein the processor is configured to:
determine, based on the voltage drop slope being greater than or equal to the second threshold, the slope change rate during a second time interval.

8. The control apparatus of claim 4, wherein the processor is configured to:
determine, based on the slope change rate being greater than or equal to the third threshold, that the power supply is in an abnormal state.

9. The control apparatus of claim 8, wherein the processor is configured to, based on the power supply being in the abnormal state:
control the host device to generate an operation control signal based on a real-time control signal of the host device; and
control the memory device to store the operation control signal.

10. The control apparatus of claim 4, wherein the processor is configured to, based on the slope change rate being greater than or equal to the third threshold, calculate:
a first value by dividing the first threshold by the voltage value,
a second value by dividing the second threshold by the voltage drop slope, and
a third value by dividing the third threshold by the slope change rate.

11. The control apparatus of claim 10, wherein the processor is configured to calculate a fourth value as a weighted sum of the first value, the second value, and the third value.

12. The control apparatus of claim 11, wherein the processor is configured to:
determine, based on the fourth value being greater than or equal to a fourth threshold, that the power supply is in an abnormal state.

13. A control method performed by an apparatus, the control method comprising:
receiving, by a processor of the apparatus from a voltage sensor, an indication of a drop in voltage being supplied to a memory device associated with a host device;
determining, by the processor and based on the indication of the drop in voltage, a state of a power supply supplying the voltage to the memory device; and
controlling, by the processor and based on the determined state of the power supply, one or more operations of the memory device and the host device.

14. The control method of claim 13, further comprising:
measuring the voltage supplied to the memory device;
determining, based on the measured voltage, a voltage value, a voltage drop slope, and a slope change rate;
setting at least one threshold corresponding to the voltage value, the voltage drop slope, and the slope change rate; and
determining the state of the power supply based on:
the voltage value, the voltage drop slope, and the slope change rate; and
the at least one threshold.

15. The control method of claim 14, wherein the setting of the at least one threshold comprises:
setting a first threshold corresponding to the voltage value,
setting a second threshold corresponding to the voltage drop slope, and
setting a third threshold corresponding to the slope change rate.

16. The control method of claim 15, further comprising:
assigning a first weight to the first threshold, a second weight to the second threshold, and a third weight to the third threshold.

17. The control method of claim 16, wherein the determining of the voltage drop slope comprising:
calculating, based on the voltage value being less than or equal to the first threshold, the voltage drop slope during a first time interval.

18. The control method of claim 17, wherein the determining of the slope change rate comprises:
calculating, based on the voltage drop slope being greater than or equal to the second threshold, the slope change rate during a second time interval.

19. The control method of claim 18, wherein the determining of the state of the power supply comprises:
determining, based on the slope change rate being greater than or equal to the third threshold, that the power supply is in an abnormal state.

20. The control method of claim 19, further comprising, based on the power supply being in the abnormal state:
controlling the host device to generate an operation control signal based on a real-time control signal of the host device; and
controlling the memory device to store the operation control signal.
